(19) United States
(12) Patent Application Publication
(10) Pub. No.: US 2023/0110225 A1
(43) Pub. Date: Apr. 13, 2023

(54) ARRAY SUBSTRATE, DISPLAY PANEL AND DISPLAY DEVICE HAVING THE ARRAY SUBSTRATE

(71) Applicant: Shenzhen China Star Optoelectronics Semiconductor Display Technology Co., Ltd., Shenzhen, Guangdong (CN)

(72) Inventor: Jing ZHU, Shenzhen, Guangdong (CN)

(73) Assignee: Shenzhen China Star Optoelectronics Semiconductor Display Technology Co., Ltd., Shenzhen, Guangdong (CN)

(21) Appl. No.: 16/963,254

(22) PCT Filed: May 20, 2020
(86) PCT No.: PCT/CN2020/091347

§ 371 Date: Jul. 20, 2020

(30) Foreign Application Priority Data
May 9, 2020 (CN) 202010386528.2

(51) Int. Cl. H01L 27/12; G02F 1/1362

(52) U.S. Cl. CPC H01L 27/124; G02F 1/136286

(57) ABSTRACT

An array substrate is disclosed. By providing a plurality of transfer line units each including at least two parallel transfer lines, a fall time of the scan signals can be significantly reduced and a charging rate of each subpixel electrode can be increased, so that display image quality can be improved. A display panel and a display device each having the array substrate are further disclosed.

### BACKGROUND OF INVENTION

### 1. Field of Invention

The present invention relates to a technical field of displays, and particularly to, an array substrate, and a display panel and a display device each having the array substrate.

### 2. Related Art

Currently, large-sized, high-resolution, and ultra-narrow liquid crystal display panels are becoming a development trend in display panel industries. Liquid crystal displays generally include array substrates, color filter substrates, and liquid crystal layers disposed between the array substrates and the color filter substrates.

FIG. 1 is a schematic wiring view of an array substrate in prior art. As shown in FIG. 1, the array substrate is divided into a display area AA′ and a non-display area surrounding the display area AA′. A plurality of scan lines 100 extending in a transverse direction, a plurality of data lines extending in a longitudinal direction and being insulated from the scan lines, and a plurality of scan transition lines 300 extending in a longitudinal direction and being electrically connected to the scan lines are provided in the display area AA′. The non-display area includes a left frame B1′, a right frame B2′, an upper frame B3′, and a lower frame B4′. The left frame B1′, the right frame B2′, and the upper frame B3′ are for encapsulation only. In addition to encapsulation, the lower frame B4′is further provided with a plurality of chip-on-films. There are three chip-on-films shown in FIG. 1, which are chip-on-films G_COF1, G_COF2, and D_COF. Specifically, each of the chip-on-films G_COF1 and G_COF2 is electrically connected to the scan transition lines 300 to transmit scan signals to the scan lines 100 through the scan transition lines 300. The chip-on-film D_COF is electrically connected to the data lines 200 for transmitting input signals to the data lines 200.

However, since the scan transition lines 300 are arranged in parallel with the data lines 200, the scan transitions 300 are under extremely large load, thereby reducing a charging rate of each subpixel electrode in the liquid crystal display panel, resulting in poor display image quality.

### SUMMARY OF INVENTION

An object of the present invention is to provide an array substrate, and a display panel and a display device each having the array substrate to over a technical problem of pool display image quality of display panels and display devices caused by a low charging rate of each subpixel electrode in the prior art.

In a first aspect, the present invention provides an array substrate, comprising a display area provided with a plurality of scan lines and data lines, wherein the scan lines are spaced apart from each other and extend in a first direction, the data lines are spaced apart from each other and extend in a second direction, the first direction is perpendicular to the second direction, and the scan lines and the data lines are insulated from and intersect with each other; wherein the display area is further provided with a plurality of transfer line units, each of the transfer line units comprises at least two transfer lines arranged in parallel, the transfer line units are spaced apart from each other and extend in a second direction, and each of the scan lines is provided with at least a corresponding one of the transfer line units and is electrically connected to all the transfer lines of the corresponding one of the transfer line units, wherein each of the transfer lines is configured to input a scan signal to the scan line being electrically connected.

In one embodiment, each of the transfer lines is arranged to correspond to one of the data lines, different one of the transfer lines corresponds to different one of the data lines, and all the data lines correspond to all the transfer lines of each of the transfer line units are arranged adjacent to each other in sequence.

In one embodiment, each of the transfer lines is situated on a same side of the corresponding one of the data lines.

In one embodiment, the array substrate further comprises a first metal layer and a second metal layer disposed above the first metal layer, each of the scan lines is disposed in the first metal layer, and each of the data lines is disposed in the second metal layer.

In one embodiment, each of the transfer lines is disposed in the second metal layer.

In one embodiment, the array substrate further comprises a third metal layer disposed on the second metal layer, each of the transfer lines is disposed between the second metal layer and the third metal layer, and part of each of the transfer lines disposed in the second metal layer is in parallel connection with part of each of the transfer lines disposed in the third metal layer.

In one embodiment, the array substrate further comprises a non-display area, and part of all the transfer lines of each of the transfer line units extend to the non-display area and are shorted to form short connection lines.

In one embodiment, a plurality of first chip-on-films and a plurality of second chip-on-films are disposed in the non-display, wherein each of the first chip-on-films is provided to correspond to part of the short connection lines and is electrically connected to the corresponding part of the short connection lines for inputting a scan signal, and each of the second chip-on-films is provided to correspond to part of the short connection lines and is electrically connected to the corresponding part of the short connection lines for inputting a scan signal.

In a second aspect, the present invention provides a display panel, comprising an array substrate, wherein the array substrate comprises a display area provided with a plurality of scan lines and data lines, wherein the scan lines are spaced apart from each other and extend in a first direction, the data lines are spaced apart from each other and extend in a second direction, the first direction is perpendicular to the second direction, and the scan lines and the data lines are insulated from and intersect with each other; wherein the display area is further provided with a plurality of transfer line units, each of the transfer line units comprises at least two transfer lines arranged in parallel, the transfer line units are spaced apart from each other and extend in a second direction, and each of the scan lines is provided with at least a corresponding one of the transfer line units and is electrically connected to all the transfer lines of the corresponding one of the transfer line units, wherein each of the transfer lines is configured to input a scan signal to the scan line being electrically connected.

In one embodiment, each of the transfer lines is arranged to correspond to one of the data lines, different one of the transfer lines corresponds to different one of the data lines, and all the data lines correspond to all the transfer lines of each of the transfer line units are arranged adjacent to each other in sequence.

In one embodiment, each of the transfer lines is situated on a same side of the corresponding one of the data lines.

In one embodiment, the display panel further comprises a first metal layer and a second metal layer disposed above the first metal layer, each of the scan lines is disposed in the first metal layer, and each of the data lines is disposed in the second metal layer.

In one embodiment, each of the transfer lines is disposed in the second metal layer.

In one embodiment, the display panel further comprises a third metal layer disposed on the second metal layer, each of the transfer lines is disposed between the second metal layer and the third metal layer, and part of each of the transfer lines disposed in the second metal layer is in parallel connection with part of each of the transfer lines disposed in the third metal layer.

In a third embodiment, the present invention provides a display device, comprising a display panel including an array substrate, wherein the array substrate comprises a display area provided with a plurality of scan lines and data lines, wherein the scan lines are spaced apart from each other and extend in a first direction, the data lines are spaced apart from each other and extend in a second direction, the first direction is perpendicular to the second direction, and the scan lines and the data lines are insulated from and intersect with each other; wherein the display area is further provided with a plurality of transfer line units, each of the transfer line units comprises at least two transfer lines arranged in parallel, the transfer line units are spaced apart from each other and extend in a second direction, and each of the scan lines is provided with at least a corresponding one of the transfer line units and is electrically connected to all the transfer lines of the corresponding one of the transfer line units, wherein each of the transfer lines is configured to input a scan signal to the scan line being electrically connected.

In one embodiment, each of the transfer lines is arranged to correspond to one of the data lines, different one of the transfer lines corresponds to different one of the data lines, and all the data lines correspond to all the transfer lines of each of the transfer line units are arranged adjacent to each other in sequence.

In one embodiment, each of the transfer lines is situated on a same side of the corresponding one of the data lines.

In one embodiment, the display device further comprises a first metal layer and a second metal layer disposed above the first metal layer, each of the scan lines is disposed in the first metal layer, and each of the data lines is disposed in the second metal layer.

In one embodiment, each of the transfer lines is disposed in the second metal layer.

In one embodiment, the display device further comprises a third metal layer disposed on the second metal layer, each of the transfer lines is disposed between the second metal layer and the third metal layer, and part of each of the transfer lines disposed in the second metal layer is in parallel connection with part of each of the transfer lines disposed in the third metal layer.

The present invention has advantageous effects as follows: the array substrate provided by the present invention using the transfer line units to replace conventional scan transition lines to achieve scan signal transmission, and since each of the transfer line units includes at least two parallel transfer lines, resistance of each transfer line unit is less than that of the scan transition lines in the prior art, so that a fall time of the scan signals can be significantly reduced, thereby improving a charging rate of each subpixel electrode, and display image quality can be improved when the array substrate is used in the display panel and the display device.

### BRIEF DESCRIPTION OF DRAWINGS

FIG. 1 is a schematic wiring view of an array substrate in prior art.

FIG. 2 is a schematic wiring view of an array substrate in accordance with an embodiment of the present invention.

FIG. 3 is a schematic view showing film layers of an array substrate in accordance with an embodiment of the present invention.

FIG. 4 is a schematic view showing film layers of an array substrate in accordance with another embodiment of the present invention.

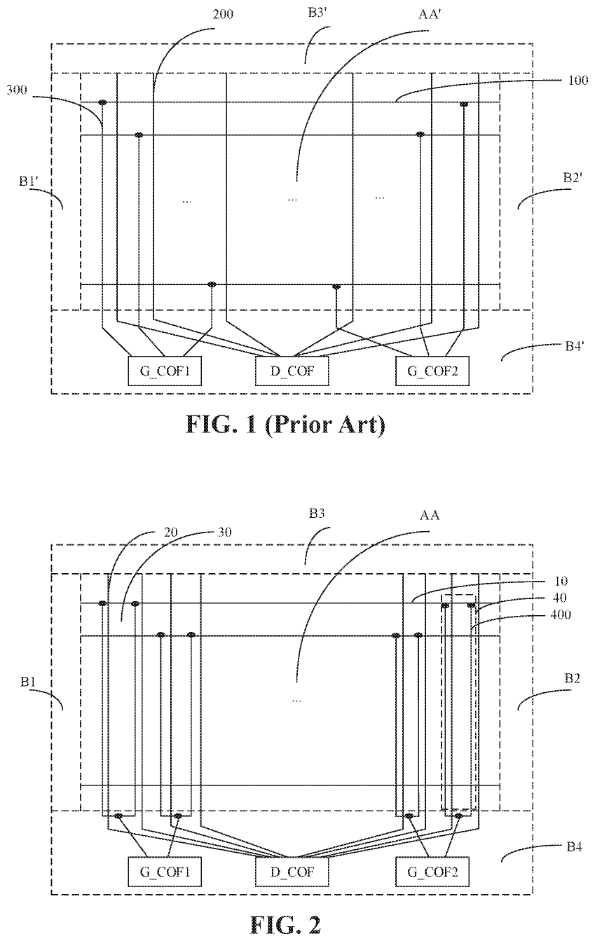

### DESCRIPTION OF PREFERRED EMBODIMENTS

To make the objectives, technical solutions, and effects of the present invention clearer and more specific, the present invention will be described in further detail below with reference to the accompanying drawings and embodiments. It should be understood that the specific embodiments described herein are only used to explain the present invention and are not intended to limit the present invention.

FIG. 2 is a schematic wiring view of an array substrate in accordance with an embodiment of the present invention. As shown in FIG. 2, the array substrate is divided into a display area AA and a non-display area surrounding the display area AA. The non-display area includes a left frame B1, a right frame B2, an upper frame B3, and a lower frame B4.

A plurality of scan lines 10 and a plurality of data lines 20 are disposed in the display area AA. The scan lines 10 are spaced apart from each other and extend in a first direction, the data lines 20 are spaced apart from each other and extend in a second direction, and the first direction is perpendicular to the second direction. In this embodiment, the first direction is a horizontal direction in FIG. 2, and the second direction is a vertical direction in FIG. 2. It can be understood that in other embodiments, the first direction may be a vertical direction, and the second direction may be a horizontal direction.

The scan lines 10 and the data lines 20 are insulated from and intersect with each other, so that the display area AA is divided into a plurality of subpixel areas 30. Each of the subpixel areas 30 is provided with a subpixel electrode (not shown in FIG. 2) and a corresponding thin-film transistor (TFT) (not shown in FIG. 2). A gate electrode of each TFT is electrically connected to a corresponding one of the scan lines 10. A source electrode of each TFT is electrically connected to a corresponding one of the data lines 20. A drain electrode of each TFT is electrically connected to a corresponding one of the pixel electrodes.

As shown in FIG. 2, the display area AA is further provided with a plurality of transfer line units 40. Each of the transfer line units 40 includes at least two transfer lines 400 arranged in parallel. Each of the transfer line units 40 shown in FIG. 2 includes two transfer lines 400 arranged in parallel. It can be understood that in other embodiments, each of the transfer line units 40 may include three or more parallel transfer lines 400. All the transfer lines 400 are spaced apart from each other and extend in the second direction.

Each of the scan lines 10 is provided with at least a corresponding one of the transfer line units 40. It should be noted that number of the transfer line units 40 corresponding to each scanning line 10 is related to a driving method for all the scanning lines 10. For example, if the driving method is a unilateral driving method, each of the scan lines 10 corresponds to one transfer line unit 40; if the driving method is a bilateral driving method, each of the scan lines 10 corresponds to two transfer line units 40, and so on. A driving method as shown in FIG. 2 is a bilateral driving method. In this manner, each of the scan lines 10 corresponds to two transfer line units 40. It can be understood that in other embodiments, a method for driving the scan lines 10 may be a unilateral driving method. In this manner, each of the scan lines 10 corresponds to one transfer line unit 40.

Each of the scan lines 10 is electrically connected to all transfer lines 400 of the corresponding one of the transfer line units 40, wherein each of the transfer lines 400 is configured to input a scan signal to the scan line 10 being electrically connected.

Based on the array substrate provided by the present invention, the transfer line units 40 replace conventional scan transition lines to transfer scan signals. Since each of the transfer line units 40 includes at least two parallel transfer lines 400, resistance of each transfer line unit 40 is less than that of the scan transition lines in the prior art, which can greatly reduce a fall time of the scan signals, thereby improving a charging rate of each subpixel electrode. When the array substrate is used in a display panel and a display device, display image quality can be improved.

In one embodiment, each of the transfer lines 400 is arranged to correspond to one of the data lines 20, and different one of the transfer lines 400 corresponds to different one of the data lines 20. In the embodiment shown in FIG. 2, each of the transfer lines 400 is situated adjacent to a corresponding one of the data lines 20 and is located on a left side of the corresponding data line 20. It can be understood that in another embodiment, each of the transfer lines 400 may be located on a right side of the corresponding data line 20; alternatively, in another embodiment, some of the transfer lines 400 are located on the left side of the corresponding data lines 20, while some of the transfer lines 400 are located on the right side of the corresponding data lines 20.

All the data lines 20 correspond to all the transfer lines 400 of each of the transfer line units 40 are arranged adjacent to each other in sequence. In the embodiment as shown in FIG. 2, each of the transfer line units 40 includes two parallel transfer lines 400. The two data lines 20 corresponding to the two parallel transfer lines 400 are arranged adjacent to each other in sequence. In other embodiments, when each of the transfer line units 40 includes three parallel transfer lines 400, the three data lines 20 corresponding to the three parallel transfer lines 400 are arranged adjacent to each other in sequence.

It can be understood that for any one of the transfer line units 40, number of the data lines 20 spanned between any adjacent two of the transfer lines 400 can be reduced when all the transfer lines 400 in each of the transfer line units 40 are disposed in the above-mentioned arrangement, thereby reducing electrostatic damage in the display area AA.

In one embodiment, each of the transfer lines 400 is situated on a same side of the corresponding one of the data lines 20.

Specifically, for any column of the subpixel area 30, each of the subpixel electrodes in a column of the subpixel areas 30 is electrically connected to a same data line 20 through corresponding TFTs, and this data line 20 is referred to as the data line 20 corresponding to the column of the subpixel areas 30.

Therefore, “each transfer line 400 corresponding to one data line 20” may be interpreted as “each transfer line 400 is disposed in a column of the subpixel areas 30. “Different one of the transfer lines 400 corresponds to different one of the data lines” may be interpreted as “different one of the transfer lines 400 is disposed in different column of the subpixel areas 30. “All the data lines 20 correspond to all the transfer lines 400 of each of the transfer line units 40 are arranged adjacent to each other in sequence” may be interpreted as “all columns of the subpixel areas 30 corresponding to all transfer lines 400 of each of the transfer line units 40 are arranged adjacent to each other in sequence.

It can be understood that for any one of the transfer line units 40, number of the data lines 20 spanned between any adjacent two of the transfer lines 400 can be reduced when all the transfer lines 400 in each of the transfer line units 40 are disposed in the above-mentioned arrangement, thereby reducing electrostatic damage in the display area AA.

In order to realize a layout in which all scan lines 10 and all data lines 20 are insulated and crossed, all scan lines 10 and all data lines 20 are respectively arranged in different metal layers of the array substrate.

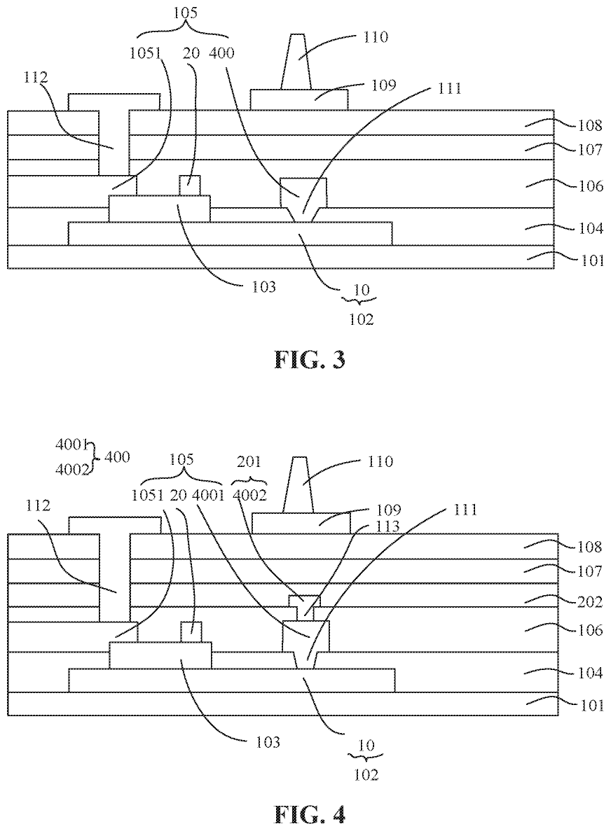

In one embodiment, each of the transfer lines 400 is configured with a single layer metal structure. As shown is FIG. 3, FIG. 3 is a schematic view showing film layers of an array substrate in accordance with an embodiment of the present invention. An array substrate includes a first metal layer 102 and a second metal layer 105 disposed above the first metal layer 102. Each of the scan lines 10 is disposed in the first metal layer 102, and each of the data lines 20 is disposed in the second metal layer 105.

Specifically, the array substrate as shown in FIG. 3 further includes a first substrate 101, an active layer 103, a first insulting layer 104, a second insulating layer 106, a color resist layer 107, a planarization layer 108, a pixel electrode layer 109, and a photo spacer 110.

The first substrate 101 is preferably a glass substrate.

The first metal layer 102 is disposed on the first substrate 101 and is configured to form the scan lines 10 and gate electrodes of TFTs integrally formed with the scan lines 10.

The active layer 103 is disposed on the first metal layer 102.

The first insulating layer 104 is disposed on the first substrate 101 and covers the first metal layer 102.

The second metal layer 105 is disposed on the first insulating layer 104 and is configured to form the data lines 20, source electrodes of TFTs integrally formed with the data lines 20, drain electrodes 1051, and transfer lines 400. Specifically, the data lines 20, and the source electrodes and the drain electrodes 1051 of the TFTs are situated on the active layer 103, respectively. Each of the transfer lines 400 is connected to a corresponding one of the scan lines 10 through a first via hole 111, wherein the first via hole 111 is formed in the first insulating layer 104 and is situated on the first metal layer 102.

The second insulating layer 106 is disposed on the first insulating layer 104 and covers the second metal layer 105.

The color resist layer 107 is disposed on the second insulating layer 106.

The planarization layer 108 is disposed on the color resist layer 107.

The pixel electrode layer 109 is disposed on the planarization layer 108 and is connected to the drain electrode 1051 of the TFT through a second via hole 112, wherein the second via hole 112 is formed in the second insulating layer 106, the color resist layer 107, and the planarization layer 108, and is situated on the drain electrode 1051 of the TFT.

The column photo spacer 110 is disposed on the pixel electrode layer 109.

In one embodiment, each of the transfer lines 400 is configured with a two-layered metal structure. As shown in FIG. 4, FIG. 4 is a schematic view showing film layers of an array substrate in accordance with another embodiment of the present invention. An array substrate includes a first metal layer 102, a second metal layer 105 disposed above the first metal layer 102, and a third metal layer 201 disposed on the second metal layer 105. Each of the scan lines 10 is disposed in the first metal layer 102, and each of the data lines 20 is disposed in the second metal layer 105. Each of the transfer lines 400 is disposed between the second metal layer 105 and the third metal layer 201 and includes a first part 4001 of the second metal layer 105 and a second part 4002 of the third meal layer 201, wherein the first part 4001 and the second part 4002 are in parallel connection with each other.

Specifically, the array substrate as shown in FIG. 4 further includes a first substrate 101, an active layer 103, a first insulting layer 104, a second insulating layer 106, a third insulating layer 202, a color resist layer 107, a planarization layer 108, a pixel electrode layer 109, and a photo spacer 110.

The first substrate 101 is preferably a glass substrate.

The first metal layer 102 is disposed on the first substrate 101 and is configured to form the scan lines 10 and gate electrodes of TFTs integrally formed with the scan lines 10.

The active layer 103 is disposed on the first metal layer 102.

The first insulating layer 104 is disposed on the first substrate 101 and covers the first metal layer 102.

The second metal layer 105 is disposed on the first insulating layer 104 and is configured to form the data lines 20, source electrodes of TFTs integrally formed with the data lines 20, drain electrodes 1051, and the first parts 4001 of the transfer lines 400. Specifically, the data lines 20, and the source electrodes and the drain electrodes 1051 of the TFTs are situated on the active layer 103, respectively. Each of the first parts 4001 of the transfer lines 400 is connected to a corresponding one of the scan lines 10 through a first via hole 111, wherein the first via hole 111 is formed in the first insulating layer 104 and is situated on the first metal layer 102.

The second insulating layer 106 is disposed on the first insulating layer 104 and covers the second metal layer 105.

The third metal layer 201 is disposed on the second insulating layer 106 and is configured to form the second parts 4002 of the transfer lines 400. Each of the second parts 4002 of the transfer lines 400 is connected to a corresponding one of the first parts 4001 of the transfer lines 400 through a third via hole 113.

The third insulating layer 202 is disposed on the second insulating layer 106 and covers the third metal layer 201.

The color resist layer 107 is disposed on the second insulating layer 106.

The planarization layer 108 is disposed on the color resist layer 107.

The pixel electrode layer 109 is disposed on the planarization layer 108 and is connected to the drain electrode 1051 of the TFT through a second via hole 112, wherein the second via hole 112 is formed in the second insulating layer 106, the third insulating layer 202, the color resist layer 107, and the planarization layer 108, and is situated on the drain electrode 1051 of the TFT.

The column photo spacer 110 is disposed on the pixel electrode layer 109.

It can be understood that in the present embodiment each of the transfer lines 400 is a two-layered metal structure and is formed between the second metal layer 105 and the third metal layer 201. Part of each of the transfer lines 400 in the second metal layer 105 is in parallel connection with part of each of the transfer lines 400 in the third metal 201. Compared to a single layer metal structure, the two-layered metal structure can reduce resistance of each transfer line 400, thereby enabling each of the transfer lines 400 having a lower resistance. Therefore, a fall time of the scan signals can be further shortened, and a charging rate of each subpixel electrode can be improved. When the array substrate is used in a display panel and a display device, display image quality can be further improved.

In one embodiment, the array substrate further includes a non-display area including a left frame B1, a right frame B2, an upper frame B3, and a lower frame B4.

As shown in FIG. 2, part of all the transfer lines 400 of each of the transfer line units 40 extend to the non-display area and are shorted to form short connection lines. All the short connection lines as shown in FIG. 2 are disposed on the lower frame B4.

In one embodiment, as shown in FIG. 2, a plurality of first chip-on-films and a plurality of second chip-on-films are disposed in the non-display. As shown in FIG. 2, the first chip-on-films and the second chip-on-films are all disposed on the lower frame B4, wherein a number of the first chip-on-films is two, indicated as G_COF1 and G_COF2, respectively, and a number of the second chip-on-film is one, indicated as D_COF.

Each of the first chip-on-films is provided to correspond to part of the short connection lines and is electrically connected to the corresponding part of the short connection lines for inputting a scan signal. For example, each of the first chip-on-films G_COF1 and G_COF2 in FIG. 2 corresponds to part of the short connection lines and is electrically connected to the corresponding part of the short connection lines for inputting a scan signal. Each of the second chip-on-films corresponds to part of the data lines and is electrically connected to the corresponding part of the data lines for inputting a data signal. For example, a second chip-on-film D_COF in FIG. 2 is corresponding to a plurality of the data lines 20 and is electrically connected and inputting a data signal to the corresponding data lines 20.

The present invention further provides a display panel. The display panel includes an array substrate. FIG. 2 is a schematic wiring view of an array substrate in accordance with an embodiment of the present invention. As shown in FIG. 2, the array substrate is divided into a display area AA and a non-display area surrounding the display area AA. The non-display area includes a left frame B1, a right frame B2, an upper frame B3, and a lower frame B4.

A plurality of scan lines 10 and a plurality of data lines 20 are disposed in the display area AA. The scan lines 10 are spaced apart from each other and extend in a first direction, the data lines 20 are spaced apart from each other and extend in a second direction, and the first direction is perpendicular to the second direction. In this embodiment, the first direction is a horizontal direction in FIG. 2, and the second direction is a vertical direction in FIG. 2. It can be understood that in other embodiments, the first direction may be a vertical direction, and the second direction may be a horizontal direction.

The scan lines 10 and the data lines 20 are insulated from and intersect with each other, so that the display area AA is divided into a plurality of subpixel areas 30. Each of the subpixel areas 30 is provided with a subpixel electrode (not shown in FIG. 2) and a corresponding thin-film transistor (TFT) (not shown in FIG. 2). A gate electrode of each TFT is electrically connected to a corresponding one of the scan lines 10. A source electrode of each TFT is electrically connected to a corresponding one of the data lines 20. A drain electrode of each TFT is electrically connected to a corresponding one of the pixel electrodes.

As shown in FIG. 2, the display area AA is further provided with a plurality of transfer line units 40. Each of the transfer line units 40 includes at least two transfer lines 400 arranged in parallel. Each of the transfer line units 40 shown in FIG. 2 includes two transfer lines 400 arranged in parallel. It can be understood that in other embodiments, each of the transfer line units 40 may include three or more parallel transfer lines 400. All the transfer lines 400 are spaced apart from each other and extend in the second direction.

Each of the scan lines 10 is provided with at least a corresponding one of the transfer line units 40. It should be noted that number of the transfer line units 40 corresponding to each scanning line 10 is related to a driving method for all the scanning lines 10. For example, if the driving method is a unilateral driving method, each of the scan lines 10 corresponds to one transfer line unit 40; if the driving method is a bilateral driving method, each of the scan lines 10 corresponds to two transfer line units 40, and so on. A driving method as shown in FIG. 2 is a bilateral driving method. In this manner, each of the scan lines 10 corresponds to two transfer line units 40. It can be understood that in other embodiments, a method for driving the scan lines 10 may be a unilateral driving method. In this manner, each of the scan lines 10 corresponds to one transfer line unit 40.

Each of the scan lines 10 is electrically connected to all transfer lines 400 of the corresponding one of the transfer line units 40, wherein each of the transfer lines 400 is configured to input a scan signal to the scan line 10 being electrically connected.

Based on the display panel provided by the present invention, since the transfer line units 40 of the array substrate replace conventional scan transition lines to achieve scan signal transmission, and each of the transfer line units 40 includes at least two parallel transfer lines 400, resistance of each transfer line unit 40 is less than that of the scan transition lines in the prior art, which can greatly reduce a fall time of the scan signals, thereby improving a charging rate of each subpixel electrode as well as improving display image quality.

In one embodiment, each of the transfer lines 400 is arranged to correspond to one of the data lines 20, and different one of the transfer lines 400 corresponds to different one of the data lines 20. In the embodiment shown in FIG. 2, each of the transfer lines 400 is situated adjacent to a corresponding one of the data lines 20 and is located on a left side of the corresponding data line 20. It can be understood that in another embodiment, each of the transfer lines 400 may be located on a right side of the corresponding data line 20; alternatively, in another embodiment, some of the transfer lines 400 are located on the left side of the corresponding data lines 20, while some of the transfer lines 400 are located on the right side of the corresponding data lines 20.

All the data lines 20 correspond to all the transfer lines 400 of each of the transfer line units 40 are arranged adjacent to each other in sequence. In the embodiment as shown in FIG. 2, each of the transfer line units 40 includes two parallel transfer lines 400. The two data lines 20 corresponding to the two parallel transfer lines 400 are arranged adjacent to each other in sequence. In other embodiments, when each of the transfer line units 40 includes three parallel transfer lines 400, the three data lines 20 corresponding to the three parallel transfer lines 400 are arranged adjacent to each other in sequence.

It can be understood that for any one of the transfer line units 40, number of the data lines 20 spanned between any adjacent two of the transfer lines 400 can be reduced when all the transfer lines 400 in each of the transfer line units 40 are disposed in the above-mentioned arrangement, thereby reducing electrostatic damage in the display area AA.

In one embodiment, each of the transfer lines 400 is situated on a same side of the corresponding one of the data lines 20.

Specifically, for any column of the subpixel area 30, each of the subpixel electrodes in a column of the subpixel areas 30 is electrically connected to a same data line 20 through corresponding TFTs, and this data line 20 is referred to as the data line 20 corresponding to the column of the subpixel areas 30.

Therefore, “each transfer line 400 corresponding to one data line 20” may be interpreted as “each transfer line 400 is disposed in a column of the subpixel areas 30. “Different one of the transfer lines 400 corresponds to different one of the data lines” may be interpreted as “different one of the transfer lines 400 is disposed in different column of the subpixel areas 30. “All the data lines 20 correspond to all the transfer lines 400 of each of the transfer line units 40 are arranged adjacent to each other in sequence” may be interpreted as “all columns of the subpixel areas 30 corresponding to all transfer lines 400 of each of the transfer line units 40 are arranged adjacent to each other in sequence.

It can be understood that for any one of the transfer line units 40, number of the data lines 20 spanned between any adjacent two of the transfer lines 400 can be reduced when all the transfer lines 400 in each of the transfer line units 40 are disposed in the above-mentioned arrangement, thereby reducing electrostatic damage in the display area AA.

In order to realize a layout in which all scan lines 10 and all data lines 20 are insulated and crossed, all scan lines 10 and all data lines 20 are respectively arranged in different metal layers of the array substrate.

In one embodiment, each of the transfer lines 400 is configured with a single layer metal structure. As shown is FIG. 3, FIG. 3 is a schematic view showing film layers of an array substrate in accordance with an embodiment of the present invention. An array substrate includes a first metal layer 102 and a second metal layer 105 disposed above the first metal layer 102. Each of the scan lines 10 is disposed in the first metal layer 102, and each of the data lines 20 is disposed in the second metal layer 105.

Specifically, the array substrate as shown in FIG. 3 further includes a first substrate 101, an active layer 103, a first insulting layer 104, a second insulating layer 106, a color resist layer 107, a planarization layer 108, a pixel electrode layer 109, and a photo spacer 110.

The first substrate 101 is preferably a glass substrate.

The first metal layer 102 is disposed on the first substrate 101 and is configured to form the scan lines 10 and gate electrodes of TFTs integrally formed with the scan lines 10.

The active layer 103 is disposed on the first metal layer 102.

The first insulating layer 104 is disposed on the first substrate 101 and covers the first metal layer 102.

The second metal layer 105 is disposed on the first insulating layer 104 and is configured to form the data lines 20, source electrodes of TFTs integrally formed with the data lines 20, drain electrodes 1051, and transfer lines 400. Specifically, the data lines 20, and the source electrodes and the drain electrodes 1051 of the TFTs are situated on the active layer 103, respectively. Each of the transfer lines 400 is connected to a corresponding one of the scan lines 10 through a first via hole 111, wherein the first via hole 111 is formed in the first insulating layer 104 and is situated on the first metal layer 102.

The second insulating layer 106 is disposed on the first insulating layer 104 and covers the second metal layer 105.

The color resist layer 107 is disposed on the second insulating layer 106.

The planarization layer 108 is disposed on the color resist layer 107.

The pixel electrode layer 109 is disposed on the planarization layer 108 and is connected to the drain electrode 1051 of the TFT through a second via hole 112, wherein the second via hole 112 is formed in the second insulating layer 106, the color resist layer 107, and the planarization layer 108, and is situated on the drain electrode 1051 of the TFT.

The column photo spacer 110 is disposed on the pixel electrode layer 109.

In one embodiment, each of the transfer lines 400 is configured with a two-layered metal structure. As shown in FIG. 4, FIG. 4 is a schematic view showing film layers of an array substrate in accordance with another embodiment of the present invention. An array substrate includes a first metal layer 102, a second metal layer 105 disposed above the first metal layer 102, and a third metal layer 201 disposed on the second metal layer 105. Each of the scan lines 10 is disposed in the first metal layer 102, and each of the data lines 20 is disposed in the second metal layer 105. Each of the transfer lines 400 is disposed between the second metal layer 105 and the third metal layer 201 and includes a first part 4001 of the second metal layer 105 and a second part 4002 of the third meal layer 201, wherein the first part 4001 and the second part 4002 are in parallel connection with each other.

Specifically, the array substrate as shown in FIG. 4 further includes a first substrate 101, an active layer 103, a first insulting layer 104, a second insulating layer 106, a third insulating layer 202, a color resist layer 107, a planarization layer 108, a pixel electrode layer 109, and a photo spacer 110.

The first substrate 101 is preferably a glass substrate.

The first metal layer 102 is disposed on the first substrate 101 and is configured to form the scan lines 10 and gate electrodes of TFTs integrally formed with the scan lines 10.

The active layer 103 is disposed on the first metal layer 102.

The first insulating layer 104 is disposed on the first substrate 101 and covers the first metal layer 102.

The second metal layer 105 is disposed on the first insulating layer 104 and is configured to form the data lines 20, source electrodes of TFTs integrally formed with the data lines 20, drain electrodes 1051, and the first parts 4001 of the transfer lines 400. Specifically, the data lines 20, and the source electrodes and the drain electrodes 1051 of the TFTs are situated on the active layer 103, respectively. Each of the first parts 4001 of the transfer lines 400 is connected to a corresponding one of the scan lines 10 through a first via hole 111, wherein the first via hole 111 is formed in the first insulating layer 104 and is situated on the first metal layer 102.

The second insulating layer 106 is disposed on the first insulating layer 104 and covers the second metal layer 105.

The third metal layer 201 is disposed on the second insulating layer 106 and is configured to form the second parts 4002 of the transfer lines 400. Each of the second parts 4002 of the transfer lines 400 is connected to a corresponding one of the first parts 4001 of the transfer lines 400 through a third via hole 113.

The third insulating layer 202 is disposed on the second insulating layer 106 and covers the third metal layer 201.

The color resist layer 107 is disposed on the second insulating layer 106.

The planarization layer 108 is disposed on the color resist layer 107.

The pixel electrode layer 109 is disposed on the planarization layer 108 and is connected to the drain electrode 1051 of the TFT through a second via hole 112, wherein the second via hole 112 is formed in the second insulating layer 106, the third insulating layer 202, the color resist layer 107, and the planarization layer 108, and is situated on the drain electrode 1051 of the TFT.

The column photo spacer 110 is disposed on the pixel electrode layer 109.

It can be understood that in the present embodiment each of the transfer lines 400 is a two-layered metal structure and is formed between the second metal layer 105 and the third metal layer 201. Part of each of the transfer lines 400 in the second metal layer 105 is in parallel connection with part of each of the transfer lines 400 in the third metal 201. Compared to a single layer metal structure, the two-layered metal structure can reduce resistance of each transfer line 400, thereby enabling each of the transfer lines 400 having a lower resistance. Therefore, a fall time of the scan signals can be further shortened, and a charging rate of each subpixel electrode can be improved, so that display image quality can be further improved.

In one embodiment, the array substrate further includes a non-display area including a left frame B1, a right frame B2, an upper frame B3, and a lower frame B4.

As shown in FIG. 2, part of all the transfer lines 400 of each of the transfer line units 40 extend to the non-display area and are shorted to form short connection lines. All the short connection lines as shown in FIG. 2 are disposed on the lower frame B4.

In one embodiment, as shown in FIG. 2, a plurality of first chip-on-films and a plurality of second chip-on-films are disposed in the non-display. As shown in FIG. 2, the first chip-on-films and the second chip-on-films are all disposed on the lower frame B4, wherein a number of the first chip-on-films is two, indicated as G_COF1 and G_COF2, respectively, and a number of the second chip-on-film is one, indicated as D_COF.

Each of the first chip-on-films is provided to correspond to part of the short connection lines and is electrically connected to the corresponding part of the short connection lines for inputting a scan signal. For example, each of the first chip-on-films G_COF1 and G_COF2 in FIG. 2 corresponds to part of the short connection lines and is electrically connected to the corresponding part of the short connection lines for inputting a scan signal. Each of the second chip-on-films corresponds to part of the data lines and is electrically connected to the corresponding part of the data lines for inputting a data signal. For example, a second chip-on-film D_COF in FIG. 2 is corresponding to a plurality of the data lines 20 and is electrically connected and inputting a data signal to the corresponding data lines 20.

The present invention further provides a display device including a display panel. The display panel includes an array substrate. FIG. 2 is a schematic wiring view of an array substrate in accordance with an embodiment of the present invention. As shown in FIG. 2, the array substrate is divided into a display area AA and a non-display area surrounding the display area AA. The non-display area includes a left frame B1, a right frame B2, an upper frame B3, and a lower frame B4.

A plurality of scan lines 10 and a plurality of data lines 20 are disposed in the display area AA. The scan lines 10 are spaced apart from each other and extend in a first direction, the data lines 20 are spaced apart from each other and extend in a second direction, and the first direction is perpendicular to the second direction. In this embodiment, the first direction is a horizontal direction in FIG. 2, and the second direction is a vertical direction in FIG. 2. It can be understood that in other embodiments, the first direction may be a vertical direction, and the second direction may be a horizontal direction.

The scan lines 10 and the data lines 20 are insulated from and intersected with each other, so that the display area AA is divided into a plurality of subpixel areas 30. Each of the subpixel areas 30 is provided with a subpixel electrode (not shown in FIG. 2) and a corresponding thin-film transistor (TFT) (not shown in FIG. 2). A gate electrode of each TFT is electrically connected to a corresponding one of the scan lines 10. A source electrode of each TFT is electrically connected to a corresponding one of the data lines 20. A drain electrode of each TFT is electrically connected to a corresponding one of the pixel electrodes.

As shown in FIG. 2, the display area AA is further provided with a plurality of transfer line units 40. Each of the transfer line units 40 includes at least two transfer lines 400 arranged in parallel. Each of the transfer line units 40 shown in FIG. 2 includes two transfer lines 400 arranged in parallel. It can be understood that in other embodiments, each of the transfer line units 40 may include three or more parallel transfer lines 400. All the transfer lines 400 are spaced apart from each other and extend in the second direction.

Each of the scan lines 10 is provided with at least a corresponding one of the transfer line units 40. It should be noted that number of the transfer line units 40 corresponding to each scanning line 10 is related to a driving method for all the scanning lines 10. For example, if the driving method is a unilateral driving method, each of the scan lines 10 corresponds to one transfer line unit 40; if the driving method is a bilateral driving method, each of the scan lines 10 corresponds to two transfer line units 40, and so on. A driving method as shown in FIG. 2 is a bilateral driving method. In this manner, each of the scan lines 10 corresponds to two transfer line units 40. It can be understood that in other embodiments, a method for driving the scan lines 10 may be a unilateral driving method. In this manner, each of the scan lines 10 corresponds to one transfer line unit 40.

Each of the scan lines 10 is electrically connected to all transfer lines 400 of the corresponding one of the transfer line units 40, wherein each of the transfer lines 400 is configured to input a scan signal to the scan line 10 being electrically connected.

Based on the display device provided by the present invention, since the transfer line units 40 of the array substrate of the display panel replace conventional scan transition lines to achieve scan signal transmission, and each of the transfer line units 40 includes at least two parallel transfer lines 400, resistance of each transfer line unit 40 is less than that of the scan transition lines in the prior art, which can greatly reduce a fall time of the scan signals, thereby improving a charging rate of each subpixel electrode as well as improving display image quality.

In one embodiment, each of the transfer lines 400 is arranged to correspond to one of the data lines 20, and different one of the transfer lines 400 corresponds to different one of the data lines 20. In the embodiment shown in FIG. 2, each of the transfer lines 400 is situated adjacent to a corresponding one of the data lines 20 and is located on a left side of the corresponding data line 20. It can be understood that in another embodiment, each of the transfer lines 400 may be located on a right side of the corresponding data line 20; alternatively, in another embodiment, some of the transfer lines 400 are located on the left side of the corresponding data lines 20, while some of the transfer lines 400 are located on the right side of the corresponding data lines 20.

All the data lines 20 correspond to all the transfer lines 400 of each of the transfer line units 40 are arranged adjacent to each other in sequence. In the embodiment as shown in FIG. 2, each of the transfer line units 40 includes two parallel transfer lines 400. The two data lines 20 corresponding to the two parallel transfer lines 400 are arranged adjacent to each other in sequence. In other embodiments, when each of the transfer line units 40 includes three parallel transfer lines 400, the three data lines 20 corresponding to the three parallel transfer lines 400 are arranged adjacent to each other in sequence.

It can be understood that for any one of the transfer line units 40, number of the data lines 20 spanned between any adjacent two of the transfer lines 400 can be reduced when all the transfer lines 400 in each of the transfer line units 40 are disposed in the above-mentioned arrangement, thereby reducing electrostatic damage in the display area AA.

In one embodiment, each of the transfer lines 400 is situated on a same side of the corresponding one of the data lines 20.

Specifically, for any column of the subpixel area 30, each of the subpixel electrodes in a column of the subpixel areas 30 is electrically connected to a same data line 20 through corresponding TFTs, and this data line 20 is referred to as the data line 20 corresponding to the column of the subpixel areas 30.

Therefore, “each transfer line 400 corresponding to one data line 20” may be interpreted as “each transfer line 400 is disposed in a column of the subpixel areas 30. “Different one of the transfer lines 400 corresponds to different one of the data lines” may be interpreted as “different one of the transfer lines 400 is disposed in different column of the subpixel areas 30. “All the data lines 20 correspond to all the transfer lines 400 of each of the transfer line units 40 are arranged adjacent to each other in sequence” may be interpreted as “all columns of the subpixel areas 30 corresponding to all transfer lines 400 of each of the transfer line units 40 are arranged adjacent to each other in sequence.

It can be understood that for any one of the transfer line units 40, number of the data lines 20 spanned between any adjacent two of the transfer lines 400 can be reduced when all the transfer lines 400 in each of the transfer line units 40 are disposed in the above-mentioned arrangement, thereby reducing electrostatic damage in the display area AA.

In order to realize a layout in which all scan lines 10 and all data lines 20 are insulated and crossed, all scan lines 10 and all data lines 20 are respectively arranged in different metal layers of the array substrate.

In one embodiment, each of the transfer lines 400 is configured with a single layer metal structure. As shown is FIG. 3, FIG. 3 is a schematic view showing film layers of an array substrate in accordance with an embodiment of the present invention. An array substrate includes a first metal layer 102 and a second metal layer 105 disposed above the first metal layer 102. Each of the scan lines 10 is disposed in the first metal layer 102, and each of the data lines 20 is disposed in the second metal layer 105.

Specifically, the array substrate as shown in FIG. 3 further includes a first substrate 101, an active layer 103, a first insulting layer 104, a second insulating layer 106, a color resist layer 107, a planarization layer 108, a pixel electrode layer 109, and a photo spacer 110.

The first substrate 101 is preferably a glass substrate.

The first metal layer 102 is disposed on the first substrate 101 and is configured to form the scan lines 10 and gate electrodes of TFTs integrally formed with the scan lines 10.

The active layer 103 is disposed on the first metal layer 102.

The first insulating layer 104 is disposed on the first substrate 101 and covers the first metal layer 102.

The second metal layer 105 is disposed on the first insulating layer 104 and is configured to form the data lines 20, source electrodes of TFTs integrally formed with the data lines 20, drain electrodes 1051, and transfer lines 400. Specifically, the data lines 20, and the source electrodes and the drain electrodes 1051 of the TFTs are situated on the active layer 103, respectively. Each of the transfer lines 400 is connected to a corresponding one of the scan lines 10 through a first via hole 111, wherein the first via hole 111 is formed in the first insulating layer 104 and is situated on the first metal layer 102.

The second insulating layer 106 is disposed on the first insulating layer 104 and covers the second metal layer 105.

The color resist layer 107 is disposed on the second insulating layer 106.

The planarization layer 108 is disposed on the color resist layer 107.

The pixel electrode layer 109 is disposed on the planarization layer 108 and is connected to the drain electrode 1051 of the TFT through a second via hole 112, wherein the second via hole 112 is formed in the second insulating layer 106, the color resist layer 107, and the planarization layer 108, and is situated on the drain electrode 1051 of the TFT.

The column photo spacer 110 is disposed on the pixel electrode layer 109.

In one embodiment, each of the transfer lines 400 is configured with a two-layered metal structure. As shown in FIG. 4, FIG. 4 is a schematic view showing film layers of an array substrate in accordance with another embodiment of the present invention. An array substrate includes a first metal layer 102, a second metal layer 105 disposed above the first metal layer 102, and a third metal layer 201 disposed on the second metal layer 105. Each of the scan lines 10 is disposed in the first metal layer 102, and each of the data lines 20 is disposed in the second metal layer 105. Each of the transfer lines 400 is disposed between the second metal layer 105 and the third metal layer 201 and includes a first part 4001 of the second metal layer 105 and a second part 4002 of the third meal layer 201, wherein the first part 4001 and the second part 4002 are in parallel connection with each other.

Specifically, the array substrate as shown in FIG. 4 further includes a first substrate 101, an active layer 103, a first insulting layer 104, a second insulating layer 106, a third insulating layer 202, a color resist layer 107, a planarization layer 108, a pixel electrode layer 109, and a photo spacer 110.

The first substrate 101 is preferably a glass substrate.

The first metal layer 102 is disposed on the first substrate 101 and is configured to form the scan lines 10 and gate electrodes of TFTs integrally formed with the scan lines 10.

The active layer 103 is disposed on the first metal layer 102.

The first insulating layer 104 is disposed on the first substrate 101 and covers the first metal layer 102.

The second metal layer 105 is disposed on the first insulating layer 104 and is configured to form the data lines 20, source electrodes of TFTs integrally formed with the data lines 20, drain electrodes 1051, and the first parts 4001 of the transfer lines 400. Specifically, the data lines 20, and the source electrodes and the drain electrodes 1051 of the TFTs are situated on the active layer 103, respectively. Each of the first parts 4001 of the transfer lines 400 is connected to a corresponding one of the scan lines 10 through a first via hole 111, wherein the first via hole 111 is formed in the first insulating layer 104 and is situated on the first metal layer 102.

The second insulating layer 106 is disposed on the first insulating layer 104 and covers the second metal layer 105.

The third metal layer 201 is disposed on the second insulating layer 106 and is configured to form the second parts 4002 of the transfer lines 400. Each of the second parts 4002 of the transfer lines 400 is connected to a corresponding one of the first parts 4001 of the transfer lines 400 through a third via hole 113.

The third insulating layer 202 is disposed on the second insulating layer 106 and covers the third metal layer 201.

The color resist layer 107 is disposed on the second insulating layer 106.

The planarization layer 108 is disposed on the color resist layer 107.

The pixel electrode layer 109 is disposed on the planarization layer 108 and is connected to the drain electrode 1051 of the TFT through a second via hole 112, wherein the second via hole 112 is formed in the second insulating layer 106, the third insulating layer 202, the color resist layer 107, and the planarization layer 108, and is situated on the drain electrode 1051 of the TFT.

The column photo spacer 110 is disposed on the pixel electrode layer 109.

It can be understood that in the present embodiment each of the transfer lines 400 is a two-layered metal structure and is formed between the second metal layer 105 and the third metal layer 201. Part of each of the transfer lines 400 in the second metal layer 105 is in parallel connection with part of each of the transfer lines 400 in the third metal 201. Compared to a single layer metal structure, the two-layered metal structure can reduce resistance of each transfer line 400, thereby enabling each of the transfer lines 400 having a lower resistance. Therefore, a fall time of the scan signals can be further shortened, and a charging rate of each subpixel electrode can be improved. When the array substrate is used in a display panel and a display device, display image quality can be further improved.

In one embodiment, the array substrate further includes a non-display area including a left frame B1, a right frame B2, an upper frame B3, and a lower frame B4.

As shown in FIG. 2, part of all the transfer lines 400 of each of the transfer line units 40 extend to the non-display area and are shorted to form short connection lines. All the short connection lines as shown in FIG. 2 are disposed on the lower frame B4.

In one embodiment, as shown in FIG. 2, a plurality of first chip-on-films and a plurality of second chip-on-films are disposed in the non-display. As shown in FIG. 2, the first chip-on-films and the second chip-on-films are all disposed on the lower frame B4, wherein a number of the first chip-on-films is two, indicated as G_COF1 and G_COF2, respectively, and a number of the second chip-on-film is one, indicated as D_COF.

Each of the first chip-on-films is provided to correspond to part of the short connection lines and is electrically connected to the corresponding part of the short connection lines for inputting a scan signal. For example, each of the first chip-on-films G_COF1 and G_COF2 in FIG. 2 corresponds to part of the short connection lines and is electrically connected to the corresponding part of the short connection lines for inputting a scan signal. Each of the second chip-on-films corresponds to part of the data lines and is electrically connected to the corresponding part of the data lines for inputting a data signal. For example, a second chip-on-film D_COF in FIG. 2 is corresponding to a plurality of the data lines 20 and is electrically connected and inputting a data signal to the corresponding data lines 20.

It can be understood that, for those of ordinary skill in the art, equivalent replacements or changes can be made according to the technical solutions and inventive concepts of the present invention, and all such changes or replacements should fall within the protection scope of the appended claims of the present invention.

What is claimed is:

1. An array substrate, comprising:
a display area provided with a plurality of scan lines and data lines, wherein the scan lines are spaced apart from each other and extend in a first direction, the data lines are spaced apart from each other and extend in a second direction, the first direction is perpendicular to the second direction, and the scan lines and the data lines are insulated from and intersect with each other;
wherein the display area is further provided with a plurality of transfer line units, each of the transfer line units comprises at least two transfer lines arranged in parallel, the transfer line units are spaced apart from each other and extend in a second direction, and each of the scan lines is provided with at least a corresponding one of the transfer line units and is electrically connected to all the transfer lines of the corresponding one of the transfer line units, wherein each of the transfer lines is configured to input a scan signal to the scan line being electrically connected.

2. The array substrate of claim 1, wherein each of the transfer lines is arranged to correspond to one of the data lines, different one of the transfer lines corresponds to different one of the data lines, and all the data lines correspond to all the transfer lines of each of the transfer line units are arranged adjacent to each other in sequence.

3. The array substrate of claim 2, wherein each of the transfer lines is situated on a same side of the corresponding one of the data lines.

4. The array substrate of claim 3, further comprising a first metal layer and a second metal layer disposed above the first metal layer, each of the scan lines is disposed in the first metal layer, and each of the data lines is disposed in the second metal layer.

5. The array substrate of claim 4, wherein each of the transfer lines is disposed in the second metal layer.

6. The array substrate of claim 4, further comprising a third metal layer disposed on the second metal layer, each of the transfer lines is disposed between the second metal layer and the third metal layer, and part of each of the transfer lines disposed in the second metal layer is in parallel connection with part of each of the transfer lines disposed in the third metal layer.

7. The array substrate of claim 1, further comprising a non-display area, and part of all the transfer lines of each of the transfer line units extend to the non-display area and are shorted to form short connection lines.

8. The array substrate of claim 7, wherein a plurality of first chip-on-films and a plurality of second chip-on-films are disposed in the non-display, wherein each of the first chip-on-films is provided to correspond to part of the short connection lines and is electrically connected to the corresponding part of the short connection lines for inputting a scan signal, and each of the second chip-on-films is provided to correspond to part of the short connection lines and is electrically connected to the corresponding part of the short connection lines for inputting a scan signal.

9. A display panel, comprising:
an array substrate, wherein the array substrate comprises a display area provided with a plurality of scan lines and data lines, wherein the scan lines are spaced apart from each other and extend in a first direction, the data lines are spaced apart from each other and extend in a second direction, the first direction is perpendicular to the second direction, and the scan lines and the data lines are insulated from and intersect with each other;
wherein the display area is further provided with a plurality of transfer line units, each of the transfer line units comprises at least two transfer lines arranged in parallel, the transfer line units are spaced apart from each other and extend in a second direction, and each of the scan lines is provided with at least a corresponding one of the transfer line units and is electrically connected to all the transfer lines of the corresponding one of the transfer line units, wherein each of the transfer lines is configured to input a scan signal to the scan line being electrically connected.

10. The display panel of claim 9, wherein each of the transfer lines is arranged to correspond to one of the data lines, different one of the transfer lines corresponds to different one of the data lines, and all the data lines correspond to all the transfer lines of each of the transfer line units are arranged adjacent to each other in sequence.

11. The display panel of claim 10, wherein each of the transfer lines is situated on a same side of the corresponding one of the data lines.

12. The display panel of claim 11, further comprising a first metal layer and a second metal layer disposed above the first metal layer, each of the scan lines is disposed in the first metal layer, and each of the data lines is disposed in the second metal layer.

13. The display panel of claim 12, wherein each of the transfer lines is disposed in the second metal layer.

14. The display panel of claim 12, further comprising a third metal layer disposed on the second metal layer, each of the transfer lines is disposed between the second metal layer and the third metal layer, and part of each of the transfer lines disposed in the second metal layer is in parallel connection with part of each of the transfer lines disposed in the third metal layer.

15. A display device, comprising a display panel including an array substrate, wherein the array substrate comprises a display area provided with a plurality of scan lines and data lines, wherein the scan lines are spaced apart from each other and extend in a first direction, the data lines are spaced apart from each other and extend in a second direction, the first direction is perpendicular to the second direction, and the scan lines and the data lines are insulated from and intersect with each other;
wherein the display area is further provided with a plurality of transfer line units, each of the transfer line units comprises at least two transfer lines arranged in parallel, the transfer line units are spaced apart from each other and extend in a second direction, and each of the scan lines is provided with at least a corresponding one of the transfer line units and is electrically connected to all the transfer lines of the corresponding one of the transfer line units, wherein each of the transfer lines is configured to input a scan signal to the scan line being electrically connected.

16. The display device of claim 15, wherein each of the transfer lines is arranged to correspond to one of the data lines, different one of the transfer lines corresponds to different one of the data lines, and all the data lines correspond to all the transfer lines of each of the transfer line units are arranged adjacent to each other in sequence.

17. The display device of claim 16, wherein each of the transfer lines is situated on a same side of the corresponding one of the data lines.

18. The display device of claim 17, further comprising a first metal layer and a second metal layer disposed above the first metal layer, each of the scan lines is disposed in the first metal layer, and each of the data lines is disposed in the second metal layer.

19. The display device of claim 18, wherein each of the transfer lines is disposed in the second metal layer.

20. The display device of claim 18, further comprising a third metal layer disposed on the second metal layer, each of the transfer lines is disposed between the second metal layer and the third metal layer, and part of each of the transfer lines disposed in the second metal layer is in parallel connection with part of each of the transfer lines disposed in the third metal layer.
